(19) United States
(12) Patent Application Publication
(10) Pub. No.: US 2014/0174908 A1
(43) Pub. Date: Jun. 26, 2014

(54) SCANDIUM-ALUMINUM ALLOY SPUTTERING TARGETS

(71) Applicant: Avago Technologies General IP (Singapore) Pte. Ltd., Singapore (SG)

(72) Inventors: Chris Feng, Fort Collins, CO (US); Tangshiun Yeh, Fort Collins, CO (US); John Choy, Westminster, CO (US); Kevin J. Grannen, Thornton, CO (US); Phil Nikkel, Loveland, CO (US)

(73) Assignee: Avago Technologies General IP (Singapore) Pte. Ltd., Singapore (SG)

(21) Appl. No.: 14/194,022

(22) Filed: Feb. 28, 2014

Related U.S. Application Data
(63) Continuation-in-part of application No. 14/092,026, filed on Nov. 27, 2013.
Application No. 14/092,026 is a continuation-in-part of application No. 14/092,077, filed on Nov. 27, 2013.
Application No. 14/092,077 is a continuation-in-part of application No. 13/955,774, filed on Jul. 31, 2013.
Application No. 13/955,774 is a continuation-in-part of application No. 13/781,491, filed on Feb. 28, 2013.
Application No. 13/781,491 is a continuation-in-part of application No. 13/663,449, filed on Oct. 29, 2012.
Application No. 13/663,449 is a continuation-in-part of application No. 13/208,883, filed on Aug. 12, 2011.
Application No. 13/208,883 is a continuation-in-part of application No. 13/074,262, filed on Mar. 29, 2011.
Application No. 13/074,262 is a continuation-in-part of application No. 13/766,993, filed on Feb. 14, 2013.
Application No. 13/766,993 is a continuation-in-part of application No. 13/660,941, filed on Oct. 25, 2012.
Application No. 13/660,941 is a continuation-in-part of application No. 13/767,754, filed on Feb. 14, 2013.
Application No. 13/767,754 is a continuation-in-part of application No. 14/092,793, filed on Nov. 27, 2013.

(51) Int. Cl. C23C 14/14; C23C 14/34

(52) U.S. Cl. CPC C23C 14/14; C23C 14/34
USPC 204/192.1; 164/69.1; 204/298.13; 29/592

(57) ABSTRACT

A sputtering target comprises an alloy of scandium and aluminum, wherein the alloy has a concentration of 3-10 at % scandium and 90-97 at % aluminum. The sputtering target can be used to produce a piezoelectric layer for an apparatus such as an acoustic resonator.

### CROSS-REFERENCE TO RELATED APPLICATIONS

This application is a continuation-in-part under 37 C.F.R. §1.53(b) of commonly owned U.S. patent applications Ser. Nos. 14/092,026 filed Nov. 27, 2013, Ser. No. 14/092,793 filed Nov. 27, 2013, and Ser. No. 14/092,077 filed Nov. 27, 2013, each of which is a continuation-in-part under 37 C.F.R. §1.53(b) of commonly owned U.S. patent application Ser. No. 13/955,774 filed on Jul. 31, 2013, which is a continuation-in-part of commonly owned U.S. patent application Ser. No. 13/781,491 filed on Feb. 28, 2013, which is a continuation-in-part of commonly owned U.S. patent application Ser. No. 13/663,449 filed on Oct. 29, 2012, which are hereby incorporated by reference in their entireties. U.S. patent application Ser. No. 13/955,774 is also a continuation-in-part under 37 C.F.R. §1.53(b) of commonly owned U.S. patent application Ser. No. 13/208,883 filed on Aug. 12, 2011, which is a continuation-in-part application of commonly owned U.S. patent application Ser. No. 13/074,262 filed on Mar. 29, 2011, which are hereby incorporated by reference in their entireties. U.S. patent application Ser. No. 14/092,793 is also a continuation-in-part under 37 C.F.R. §1.53(b) of commonly owned U.S. patent application Ser. No. 13/766,993 filed on Feb. 14, 2013, which is a continuation-in-part under 37 C.F.R. §1.53(b) of U.S. patent application Ser. No. 13/660,941 flied on Oct. 25, 2012, which are hereby incorporated by reference in their entireties. U.S. patent application Ser. No. 14/092,077 is also a continuation-in-part under 37 C.F.R. §1.53(b) of U.S. patent application Ser. No. 13/767,754 filed on Feb. 14, 2013.

### BACKGROUND

Acoustic resonators can be used to implement signal processing functions in various electronic applications. For example, some cellular phones and other communication devices use acoustic resonators to implement frequency filters for transmitted and/or received signals. Several different types of acoustic resonators can be used according to different applications, with examples including bulk acoustic wave (BAW) resonators such as thin film bulk acoustic resonators (FBARs), coupled resonator filters (CRFs), stacked bulk acoustic resonators (SBARs), double bulk acoustic resonators (DBARs), and solidly mounted resonators (SMRs).

A typical acoustic resonator comprises a layer of piezoelectric material sandwiched between two plate electrodes in a structure referred to as an acoustic stack. Where an input electrical signal is applied between the electrodes, reciprocal or inverse piezoelectric effect causes the acoustic stack to mechanically expand or contract depending on the polarization of the piezoelectric material. As the input electrical signal varies over time, expansion and contraction of the acoustic stack produces acoustic waves (or modes) that propagate through the acoustic resonator in various directions and are converted into an output electrical signal by the piezoelectric effect. Some of the acoustic waves achieve resonance across the acoustic stack, with the resonant frequency being determined by factors such as the materials, dimensions, and operating conditions of the acoustic stack. These and other mechanical characteristics of the acoustic resonator determine its frequency response.

One metric used to evaluate the performance of an acoustic resonator is its electromechanical coupling coefficient (kt²), which indicates the efficiency of energy transfer between the electrodes and the piezoelectric material. Other things being equal, an acoustic resonator with higher kt² is generally considered to have superior performance to an acoustic resonator with lower kt². Accordingly, it is generally desirable to use acoustic resonators with higher levels of kt² in high performance wireless applications, such as 4G and LTE applications.

The kt² of an acoustic resonator is influenced by several factors, such as the dimensions, composition, and structural properties of the piezoelectric material and electrodes. These factors, in turn, are influenced by the materials and manufacturing processes used to produce the acoustic resonator. For example, one way to improve kt² is to include scandium and/or other rare-earth elements, such as Yttrium, Erbium, etc. in the piezoelectric material of an acoustic resonator. Improvements due to scandium can be understood from the following operating principles of an example acoustic resonator.

In general, the most important vibrational mode for radio frequency (RF) filter applications is a longitudinal mode, which is in parallel with electrical field or perpendicular to FBAR surface. Other vibration waves are generally unwanted and may result in energy loss, reducing the device Q. The longitudinal mode is activated by varying electrical voltage across the FBAR, therefore electrical field across polarized charges (called dipoles, consisting of positive and negative charged ions in AlN film), resulting in contraction and expanding dependent on direction of electrical field. At a certain frequency, vibration of the dipoles is in phase with electrical field, where series resonance occurs and its correspondent frequency is called series resonant frequency, labeled Fs. Where the vibration is out of phase of electrical field (180 degree of the field), the resonator reaches to parallel resonance, and its corresponding frequency is called parallel resonant frequency, labeled Fp. Fp is always higher than Fs, and kt² is proportional to their difference. The addition of scandium alters these dipoles in such a way that a difference between Fs and Fp becomes larger, producing higher kt².

Conventional approaches to manufacturing acoustic resonators with scandium suffer from a variety of shortcomings that may result in non-uniformity of kt² across each manufactured acoustic resonator, or between different manufactured acoustic resonators. Consequently, in an ongoing effort to produce acoustic resonators with improved kt², researchers are seeking improved approaches to the design and manufacture of acoustic resonators.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a cross-sectional view of an acoustic resonator according to a representative embodiment.

FIG. 1B is a top view of the acoustic resonator of FIG. 1A according to a representative embodiment.

FIG. 2 is a graph illustrating the kt² of an acoustic resonator as a function of scandium concentration in a piezoelectric layer, according to a representative embodiment.

FIG. 3 is an illustration of a scandium aluminum alloy having different grain sizes, according to a representative embodiment.

FIG. 4 is a flowchart illustrating a method of manufacturing an acoustic resonator according to a representative embodiment.

FIG. 5 is a flowchart illustrating a method of manufacturing a sputtering target according to another representative embodiment.

FIG. 6 is a flowchart illustrating a method of manufacturing an acoustic resonator according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms ‘a’, ‘an’ and ‘the’ include both singular and plural referents, unless the context clearly dictates otherwise. Thus, for example, ‘a device’ includes one device and plural devices. The terms ‘substantial’ or ‘substantially’ mean to within acceptable limits or degree. The term ‘approximately’ means to within an acceptable limit or amount to one of ordinary skill in the art. Relative terms, such as “above,” “below,” “to ,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Other relative terms may also be used to indicate the relative location of certain features along a path such as a signal path, For instance, a second feature may be deemed to “follow” first feature along, a signal path if a signal transmitted along the path reaches the second feature before the second feature.

The described embodiments relate generally to sputtering targets that can be used to produce piezoelectric materials such as those used in acoustic resonators. For instance, in certain embodiments, an apparatus comprises a sputtering target comprising an alloy of scandium and aluminum, wherein the alloy has a concentration of 3-10 at % scandium and 90-97 at % aluminum. Similarly, in certain embodiments a method of manufacturing a sputtering target comprises forming a scandium-aluminum alloy comprising 3-10 at % scandium and 90-97 at % aluminum, and preparing the scandium-aluminum alloy for use as a sputtering target in plasma deposition equipment. In still other embodiments, a method of manufacturing an acoustic resonator structure comprises, in an atmosphere containing nitrogen gas, performing a sputtering process using a sputtering target comprising a scandium aluminum alloy having 3-10 at % scandium and 90-97 at % aluminum.

Compared to dual targets (Sc and Al targets) and Sc inlaid Al targets, Sc−Al alloy targets may provide improved process control and reduced variation of kt².

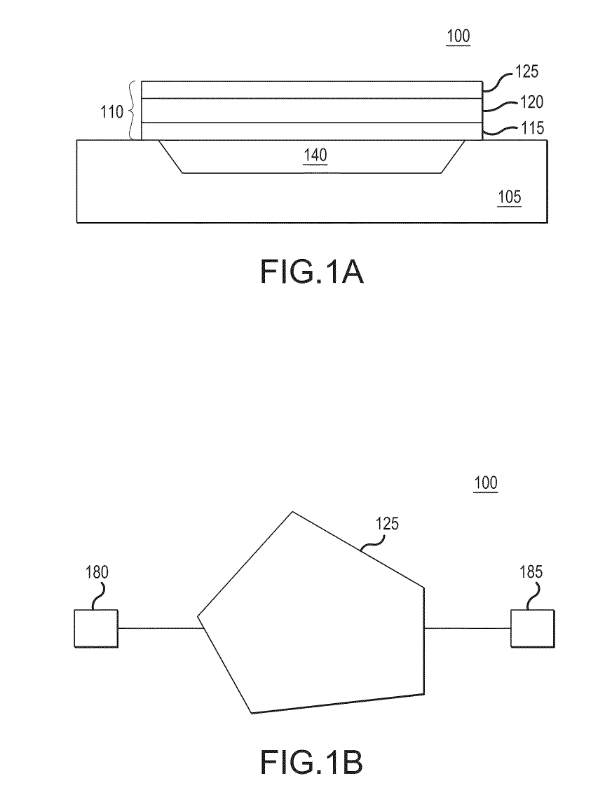

FIG. 1A is a cross-sectional view of an acoustic resonator 100 according to a representative embodiment, and FIG. 1B is a top view of acoustic resonator 100 in accordance with a representative embodiment. In the illustrated embodiments, acoustic resonator 100 comprises a film bulk acoustic resonator (FBAR) having a piezoelectric layer formed of aluminum scandium nitride (ASN). In other embodiments, acoustic resonator 100 could take another form, such as a double bulk acoustic resonator (DBAR), for example. As illustrated by FIG. 1B, acoustic resonator 100 comprises an acoustic stack having an apodized pentagonal structure, i.e. an asymmetric pentagon to distribute the spurious mode density over frequency and avoid high dissipation at any one frequency.

Referring to FIG. 1A, acoustic resonator 100 comprises a substrate 105 and an acoustic stack 110.

Substrate 105 can be formed of various types of semiconductor materials compatible with semiconductor processes, such as silicon (Si), gallium arsenide (GaAs), indium phosphide (InP), or the like, which can be useful for integrating connections and electronics, dissipating heat generated from a resonator, thus reducing size and cost and enhancing performance. Substrate 105 has an air cavity 140 located below acoustic stack 110 to allow free movement of acoustic stack 110 during operation. Air cavity 140 is typically formed by etching substrate 105 and depositing a sacrificial layer therein prior to formation of acoustic stack 110, and then removing the sacrificial layer subsequent to the formation of acoustic stack 110. As an alternative to air cavity 140, acoustic resonator 100 could include an acoustic reflector such as a Distributed Bragg Reflector (DBR), for example.

Acoustic stack 110 comprises a first electrode 115, a first piezoelectric layer 120 formed first electrode 115, and a second electrode 125 formed on piezoelectric layer 120.

First and second electrodes 115 and 125 can be formed of various conductive materials, such as metals compatible with semiconductor processes, including tungsten (W), molybdenum (Mo), aluminum (Al), platinum (Pt), ruthenium (Ru), niobium (Nb), or hafnium (Hf), for example. They can also be formed with conductive sub-layers or in combination with other types of layers, such as temperature compensating layers. In addition, first and second electrodes 115 and 125 can be formed of the same material, or they can be formed of different materials.

Second electrode 125 may further comprise a passivation layer (not shown), which can be formed of various types of materials, including AlN, silicon carbide (SiC), BSG, SiO₂, SiN, polysilicon, and the like. The thickness of the passivation layer should generally be sufficient to protect the layers of acoustic stack 110 from chemical reactions with the substances that may enter through a leak in a package.

First and second electrodes 115 and 125 are electrically connected to external circuitry via corresponding contact pads 180 and 185 shown in FIG. 1B. The contact pads are typically formed of a conductive material, such as gold or gold-tin alloy. Although not shown in FIG. 1A, the connections between these electrodes and the corresponding contact pads extend laterally outward from acoustic stack 110. The connections are generally formed of a suitable conductive material, such as Ti/W/gold.

Piezoelectric layer 120 is formed of a thin film piezoelectric comprising Al₁₋ₓScₓN. In some embodiments, piezoelectric layer 120 is formed on a seed layer (not shown) disposed over an upper surface of first electrodes 115. The seed layer can be formed of Al, for instance, to foster growth of Al₁₋ₓScₓN.

Piezoelectric layer 120 is typically formed by a sputtering process using a scandium aluminum alloy sputtering target in an atmosphere comprising at least nitrogen gas, usually in combination with one or more inert gases such as argon. The sputtering target is formed of an alloy comprising a concentration of scandium corresponding to a desired composition of piezoelectric layer 120. For instance, in some embodiments, a sputtering target may comprise approximately 3 to 10 atomic percent (at %) scandium to produce a piezoelectric layer of Al₁₋ₓScₓN where x is between approximately 0.03 and 0.10.

The sputtering process can be controlled in a variety of ways for quality purposes. One form of quality control comprises monitoring the uniformity of Sc content across the sputtering targets and adjusting the sputtering process according to the monitoring. The monitoring is typically performed by an inductively coupled plasma (ICP) measurement process that determines the ratio of Sc/Al across a target and provides feedback to an Sc content controller. Another form of quality control comprises applying a relatively fast cooling rate to the targets to reduce Sc segregation effects, which influence uniformity of kt² across a wafer. Yet another form of quality control comprises adjusting the grain size of the scandium aluminum alloy, particularly the second phase, ScAl₃, which affects kt² variation control. For instance, the scandium aluminum alloy can be designed to have a maximum average grain size (e.g., 40 μm) to enhance the kt² of devices produced using the alloy.

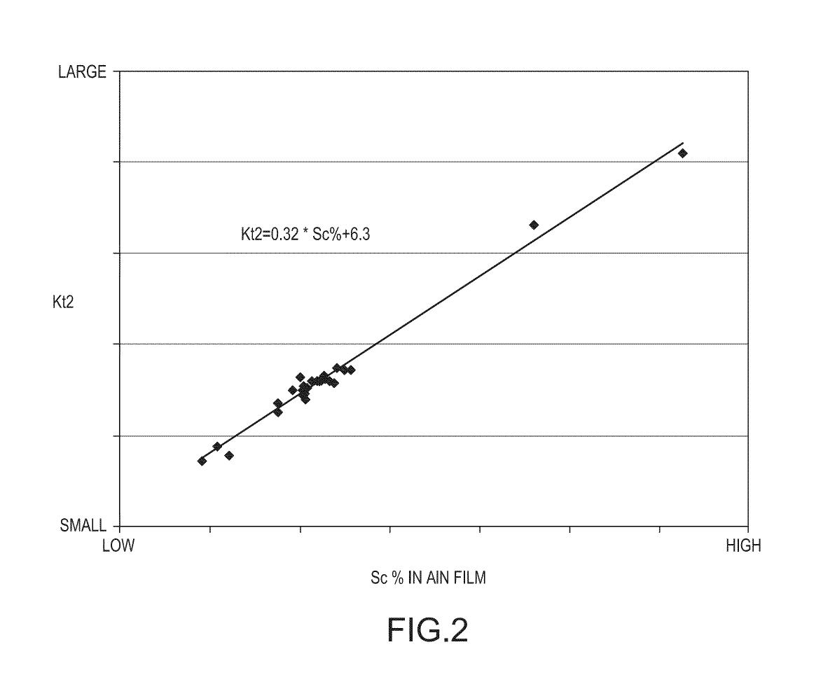

The use of aluminum scandium nitride may provide several potential benefits compared to aluminum nitride, which is used in conventional FBAR devices. First, the use of aluminum scandium nitride tends to increase the value of kt² for the piezoelectric layer, as explained in further detail below. This may allow the FBAR to be used in wide-band and enhanced performance applications, or it may allow it to be manufactured with a smaller thickness. Second, the aluminum scandium nitride tends to reduce acoustic velocity, which may allow improved performance or scaling down in thickness of all resonator layers to get back to the same frequency (and concurrent resonator area reduction). Third, the aluminum scandium nitride tends to have a higher dielectric constant, allowing further resonator area reduction for the same total impedance. Fourth, proportionally thicker electrodes tend to provide improved Q-factor, which tends to reduce insertion loss. This can be used for better performance or scaling down the effective kt² by thinning the piezoelectric layers even further for additional die shrinking. In general, the magnitude of these potential benefits may vary according to the amount of scandium in piezoelectric layer 120, as illustrated for instance, by FIG. 2.

FIG. 1B shows contact pads 180 and 185 connected to respective first and second electrodes 115 and 125 of acoustic stack 110. These contacts pads are located on substrate 105 and are used to connect acoustic resonator 100 with external circuitry. In a ladder filter comprising acoustic resonator 100 in combination with additional acoustic resonators, signal pads are typically formed in only two of the acoustic resonators while multiple ground pads are connect to shunt resonators. In particular, connection pads are formed near acoustic resonators connected to any external terminal. Other acoustic resonators can be connected to each other by internal connections without the use of contact pads.

During typical operation of acoustic resonator 100, contact pad 180 is connected to a first voltage and contact pad 185 is connected to a second voltage different from the first voltage. In one example, contact pad 180 is connected to a reference voltage such as ground, while contact pad 185 is connected to an input signal.

FIG. 2 is a graph illustrating the kt² of an acoustic resonator as a function of scandium concentration in a piezoelectric layer, according to a representative embodiment.

Referring to FIG. 2, multiple different FBARs were manufactured using Al₁₋ₓScₓN in which the relative scandium concentration “x” ranges from about 4-10 at %. The FBARs were manufactured using sputtering targets comprising an alloy of scandium and aluminum, the scandium having different concentrations as indicated by data points in the graph of FIG. 2. The FBARs were then analyzed using inductively coupled plasma (ICP) optical emission spectrometry (OES). As illustrated by the graph in FIG. 2, the kt² of those FBARs increased in a substantially linear fashion with increasing scandium concentration. More specifically, kt² increases by about 0.32 for every increased 1 at % scandium.

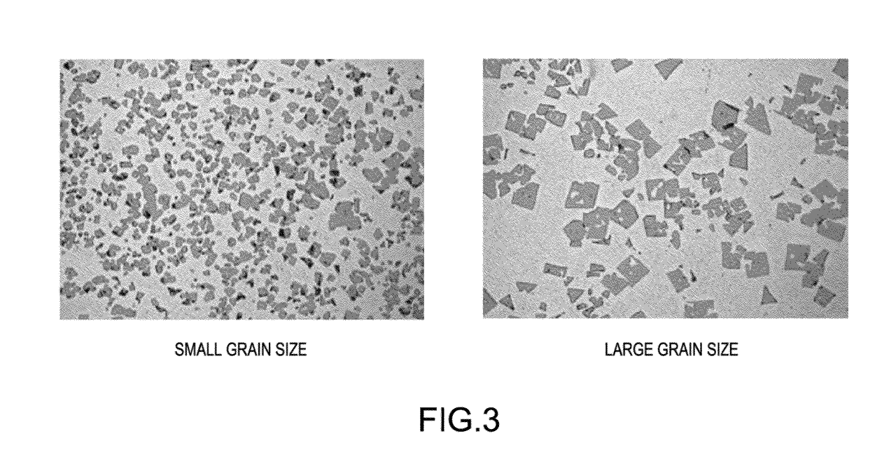

FIG. 3 is an illustration of a scandium aluminum alloy having different grain sizes, according to a representative embodiment. More particularly, it shows small and large grain sizes for a second phase of the scandium aluminum alloy, ScAl₃, which is used as a sputtering target for producing a piezoelectric layer. The use of a smaller grain size (e.g., ≦40 μm) tends to reduce target to target variation of kt² and can therefore produce acoustic resonators with more reliable performance characteristics. During manufacture of a sputtering target comprising a scandium aluminum alloy, the grain size can be reduced by performing a heat treatment on a target blank.

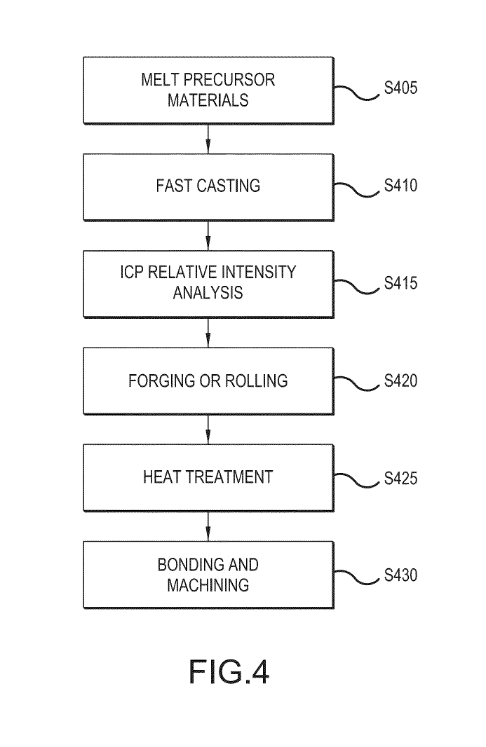

FIG. 4 is a flowchart illustrating a method of manufacturing a sputtering target comprising a scandium aluminum alloy, according to a representative embodiment. The method of FIG. 4 can be used to produce a sputtering target with a desired ratio of scandium and aluminum, a desired level of scandium segregation, and a desired grain size.

Referring to FIG. 4, the method comprises melting precursor materials in a vacuum induction furnace at high temperature inside a crucible or using an induction levitation technique (S405). The precursor materials comprise high purity scandium and aluminum with a desired ratio, typically 3-10 at % scandium and 90-97 at % aluminum. Next, the melted precursor materials are cooled by fast casting to produce a scandium aluminum alloy ingot (S410). The use of a rapid cooling rate tends to reduce scandium segregation, which in turn improves uniformity of kt² in acoustic resonators manufactured with the sputtering target. Thereafter, ICP relative intensity analysis is performed with respect to scandium content to ensure accurate composition control (S415). In the event that the scandium content does not have a desired level or is insufficiently uniform across the ingot, parameters of steps S405 and S410 may be adjusted to account for deviations when producing subsequent targets.

Subsequent to the ICP relative intensity analysis, the scandium aluminum alloy ingot is forged or rolled into a blank (S420). The forging or rolling tends to reduce the blank's porosity and microstructure. Then, a heat treatment is performed on the blank to reduce its grain size and release stress (S425). Finally, bonding and machining is performed on the heat treated blank to produce a sputtering target suitable for use with plasma deposition equipment (S430).

The quality of the sputtering target may be further verified by measuring the scandium content inside an ASM film produced from the sputtering target. Such measurement may be performed by a ICP mass spectrometry (MS) relative intensity measurement technique. A conventional ICP measurement is performed by measuring an unknown quantity of a element in a material referenced to the same element standard so that the quantity of the element is determined. The conventional method has relative large error as a result of sample preparation and equipment operation conditions. Relative intensity method utilizes a ratio of two element ICP measured intensity in a material (in this case, a scandium aluminum binary system) referenced to a pre-mixture of these two element standards, so that errors introduced by sample preparation and equipment operation conditions can be reduced substantially during the target evaluation.

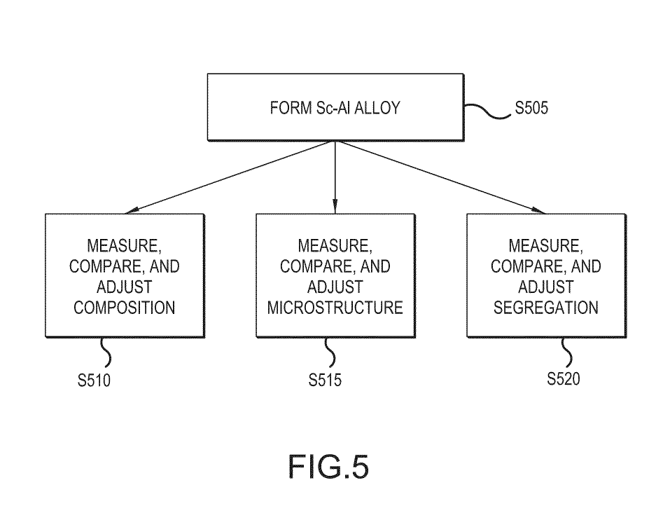

FIG. 5 is a flowchart illustrating a method of manufacturing a sputtering target according to another representative embodiment.

Referring to FIG. 5, the method comprises forming a scandium-aluminum alloy comprising 3-10 at % scandium and 90-97 at % aluminum (S505). The formation of the alloy can be performed as described above in relation to FIG. 4. The method may further comprise measuring a composition of the scandium-aluminum alloy, comparing the measured composition to a desired composition, and adjusting a composition of a subsequent sputtering target (i.e., a sputtering target formed in a subsequent process using adjusted parameters) according to the comparison (S510). In certain embodiments, the measuring of the composition comprises performing ICP-MS relative intensity measurements. The method may still further comprise measuring a microstructure of the scandium-aluminum alloy, comparing the measured microstructure to a target microstructure, and adjusting a microstructure of a subsequent sputtering target according to the comparison (S515). The measured microstructure may comprise, for instance, a grain size of ScAl₃ within the sputtering target. Moreover, the adjusting of the microstructure may comprise modifying a process parameter (e.g., heat treatment temperature, duration, etc.) to reduce the average grain size to less than Own. The method may still further comprise measuring a scandium segregation of the scandium-aluminum alloy, comparing the measured segregation to a desired segregation, and adjusting a segregation of a subsequent sputtering target according to the comparison (S520).

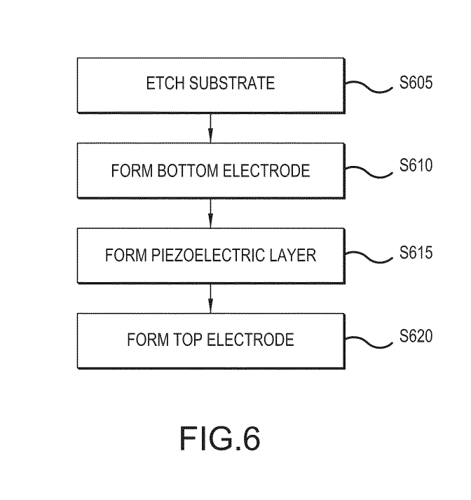

FIG. 6 is a flowchart illustrating a method of manufacturing an acoustic resonator according to a representative embodiment. For convenience of explanation, the method of FIG. 6 will be described with reference to acoustic resonator 100 of FIG. 1. However, the method is not limited to forming an acoustic resonator with the illustrated configuration.

Referring to FIG. 6, the method begins by etching substrate 105 to form air cavity 140 (S605). In a typical example, substrate 105 comprises silicon, and air cavity 140 is formed by conventional etching technologies. A sacrificial layer is typically formed in air cavity 140 prior to the formation of acoustic stack 110 and removed subsequent to formation of acoustic stack 110. After the sacrificial layer is formed in air cavity 140, bottom electrode 115 is formed over substrate 105 (S610). Bottom electrode 115 can be formed by a conventional deposition technique using materials such as those indicated above in relation to FIG. 1.

Next, piezoelectric layer 120 is formed on bottom electrode by a sputtering process using a scandium-doped aluminum sputtering target (S615). Such a processes is typically performed in an atmosphere containing nitrogen gas and with a sputtering target comprising an alloy of scandium and aluminum, comprising 3-10 at % scandium. The sputtering target may be manufactured as described above in relation to FIGS. 4 and 5, and it may include properties as described above, such as a desired grain size, uniformity, scandium segregation, and so on. Finally, top electrode 125 is formed on piezoelectric layer 120 (S620). As will be apparent to those skilled in the art, additional processing steps may be performed subsequent to the formation of top electrode 125, such as the formation of a passivation layer, electrodes, a cap, for example. Moreover, as will also be apparent to those skilled in the art, additional processing steps can be performed between or during the other operations illustrated in FIG. 6.

While example embodiments are disclosed herein, those skilled in the art will appreciate that many variations that are in accordance with the present teachings are possible and remain within the scope of the appended claims. The invention therefore is not to be restricted except within the scope of the appended claims.

1. A method of manufacturing a sputtering target, comprising:
forming a scandium-aluminum alloy comprising 3-10 at % scandium and 90-97 at % aluminum; and
preparing the scandium-aluminum alloy for use as a sputtering target in plasma deposition equipment.

2. The method of claim 1, further comprising measuring a composition of the scandium-aluminum alloy, comparing the measured composition to a desired composition, and adjusting a composition of a subsequent sputtering target according to the comparison.

3. The method of claim 2, wherein measuring the composition comprises performing inductively coupled plasma (ICP) mass spectrometry (MS).

4. The method of claim I, further comprising measuring a microstructure of the scandium-aluminum alloy, comparing the measured microstructure to a desired microstructure, and adjusting a microstructure of a subsequent sputtering target according to the comparison.

5. The method of claim 4, wherein the measured microstructure comprises a grain size of ScAl₃ within the sputtering target.

6. The method of claim 5, wherein adjusting the microstructure comprises modifying a process parameter to reduce the average grain size to less than 40 μm.

7. The method of claim 1, further comprising measuring scandium segregation of the scandium-aluminum alloy, comparing the measured segregation to a desired segregation, and adjusting a segregation of a subsequent sputtering target according to the comparison.

8. The method of claim 1, wherein forming the scandium-aluminum alloy comprises:
melting precursor materials comprising pure scandium and pure aluminum;
fast casting the melted precursor materials to produce a scandium aluminum alloy ingot;
forging or rolling the scandium aluminum alloy ingot;
heat treating the forged or rolled scandium aluminum alloy ingot; and
bonding and machining the heat treated scandium aluminum alloy ingot.

9. The method of claim 8, wherein forming the scandium-aluminum alloy further comprises:
performing inductively coupled plasma (ICP) relative intensity analysis on the scandium aluminum alloy ingot to determine its scandium content.

10. The method of claim 9, further comprising adjusting at least one process parameter for the manufacture of a subsequent sputtering target according to the determined scandium content.

11. A method of manufacturing an acoustic resonator structure, comprising:
in an atmosphere containing nitrogen gas, performing a sputtering process using a sputtering target comprising a scandium aluminum alloy having 3-10 at % scandium and 90-97 at % aluminum.

12. The method of claim 11, wherein the sputtering target comprises ScAl₃ with a grain size less than 40 μm .

13. The method of claim 11, further comprising:
forming a first electrode on a substrate;
performing the sputtering process to deposit a layer of aluminum scandium nitride (ASN) on the first electrode; and
forming a second electrode on the layer of ASN.

14. The method of claim 13, further comprising:
measuring a uniformity of an electromechanical coupling coefficient (kt²) across the layer of ASN; and
adjusting a process parameter used to produce a subsequent sputtering target according to the measurement.

15. The method of claim 14, wherein measuring the uniformity comprises performing inductively coupled plasma (ICP) mass spectrometry (MS).

16. The method of claim 13, further comprising:
measuring an electromechanical coupling coefficient (kt²) of the layer of ASN;
comparison the measured kt² with a kt² of at least one other layer of ASN produced by the sputtering target; and
adjusting a process parameter used to produce a subsequent sputtering target according to the comparison.

17. The method of claim 16, wherein the process parameter comprises a relative proportion of scandium in precursor materials used to produce a scandium aluminum alloy.

18. An apparatus, comprising:
a sputtering target comprising an alloy of scandium and aluminum, wherein the alloy has a concentration of 3-10 at % scandium and 90-97 at % aluminum.

19. The apparatus of claim 18, wherein the alloy comprises ScAl₃ with a grain size less than 40 μm.

20. The apparatus of claim 18, further comprising plasma deposition equipment incorporating the sputtering target.
